(19) United States
(12) Patent Application Publication
(10) Pub. No.: US 2014/0009894 A1
(43) Pub. Date: Jan. 9, 2014

(54) COMMUNICATION DEVICE HAVING MULTI-MODULE ASSEMBLY

(71) Applicant: Sercomm Corporation, (US)

(72) Inventor: Yi-Fei Yu, New Taipei City (TW)

(73) Assignee: Sercomm Corporation, Tapei (TW)

(21) Appl. No.: 13/870,230

(22) Filed: Apr. 25, 2013

Related U.S. Application Data
(60) Provisional application No. 61/667,461, filed on Jul. 3, 2012.

(30) Foreign Application Priority Data
Aug. 17, 2012 (TW) 101215902

(51) Int. Cl. H05K 5/00

(52) U.S. Cl. CPC H05K 5/0021
USPC 361/735

(57) ABSTRACT

A communication device having multi-module assembly is provided. The communication device includes a body, a first communication module and a second communication module. The body has a front side, a rear side and a plurality of lateral sides. The front side and the rear side both have a length dimension and a width dimension, and the lateral sides have a thickness dimension. The body is a combination of a plurality of housings with the same length dimension and the same width dimension, and the rear side of a housing ahead is connected with the front side of another housing behind. The first communication module is disposed in a first housing of the body. The second communication module is disposed in a second housing of the body.

This application claims the benefits of U.S. provisional application Ser. No. 61/667,461, filed Jul. 3, 2012, and Taiwan application Serial No. 101215902, filed Aug. 17, 2012, the subject matters of which are incorporated herein by reference.

### BACKGROUND OF THE INVENTION

1. Field of the Invention

The invention relates in general to a communication device, and more particularly to a communication device having multi-module assembly.

2. Description of the Related Art

Wireless communication system uses electromagnetic waves to communicate with fixed or mobile communication devices within the radio coverage and provides users with many communication services such as audio, data, image or multi-media service. In response to the booming demand for high speed transmission and multi-media data services, a picocell base station is provided. The picocell base station can be installed in a household and connected to a system end through existing broadband Internet, and can provide indoor wireless communication service under low power consumption. This picocell base station is normally referred as an access point base station or a femtocell, and can be connected to the Internet and a mobile service providers' network through a router or a cable modem.

Currently, a large variety of wireless communication standards are now in use, but each standard has respective specification. In order to be conformed to the most updated communication standard, new products must be continuously provided, not only shortening product life cycle but also failing to meet consumers' expectation due to high price. Moreover, new products will crowd out existing products and make them lacking competitivity. Therefore, how to increase product competitivity without shortening product life cycle has become a prominent task for the industries.

### SUMMARY OF THE INVENTION

The invention is directed to a communication device having multi-module assembly capable of increasing or replacing different types of communication modules according to users' needs and the systems used by mobile communication industries.

According to an embodiment of the present invention, a communication device having multi-module assembly is provided. The communication device includes a body, a first communication module and a second communication module. The body has a front side, a rear side and a plurality of lateral sides. The front side and the rear side both have a length dimension and a width dimension, and the lateral sides have a thickness dimension. The body is a combination of a plurality of housings with the same length dimension and the same width dimension, and the rear side of a housing ahead is connected with the front side of another housing behind. The first communication module is disposed in a first housing of the body. The second communication module is disposed in a second housing of the body.

The above and other aspects of the invention will become better understood with regard to the following detailed description of the preferred but non-limiting embodiments. The following description is made with reference to the accompanying drawings.

### BRIEF DESCRIPTION OF THE DRAWINGS

FIG. 1A and 1B respectively are an explosion diagram and an assembly diagram of a communication device having multi-module assembly according to an embodiment of the invention;

FIG. 1C shows a left-rear view of a body after assembly;

FIG. 2A and 2B are schematic diagrams of a communication device having multi-module assembly according to two embodiments of the invention;

FIG. 3 shows a right-front view of a body after assembly;

FIG. 4 shows an explosion diagram of a body according to an embodiment of the invention;

FIG. 5 shows a schematic diagram of internal structures of a body after assembly;

FIG. 6 shows a disposition diagram of antennas of communication device having multi-module assembly according to an embodiment of the invention.

### DETAILED DESCRIPTION OF THE INVENTION

A communication device having multi-module assembly is disclosed in the present embodiment based on a design similar to the combination of building blocks, the communication modules having femto solution function are designed as replaceable and independent modules, so that users can easily and conveniently add or replace required communication modules by themselves. That is, additional communication modules can be added to existing communication module for augmentation or replacement purpose to provide more communication services with different femto solutions. For example, the existing communication device has a femto solution. If the user would like to use the communication service provided by another communication system, a communication module having second femto solution function can be added to the existing communication device. If a communication module having third femto solution function needs to be added to the existing communication device for augmentation or replacement purpose, the communication module having third femto solution function can be added to the existing communication device directly or after the communication module having second femto solution function is dismounted from the existing communication device. Therefore, several communication modules can be selected and added to the communication device of the present embodiment. Furthermore, during the augmentation or replacement of communication modules, the new communication module does not require new base unit or power, but share the same base unit and power with the existing communication module, not only saving cost but also maintaining the life cycle of existing product.

A number of embodiments are disclosed below for elaborating the invention. However, the embodiments of the invention are for detailed descriptions only, not for limiting the scope of protection of the invention.

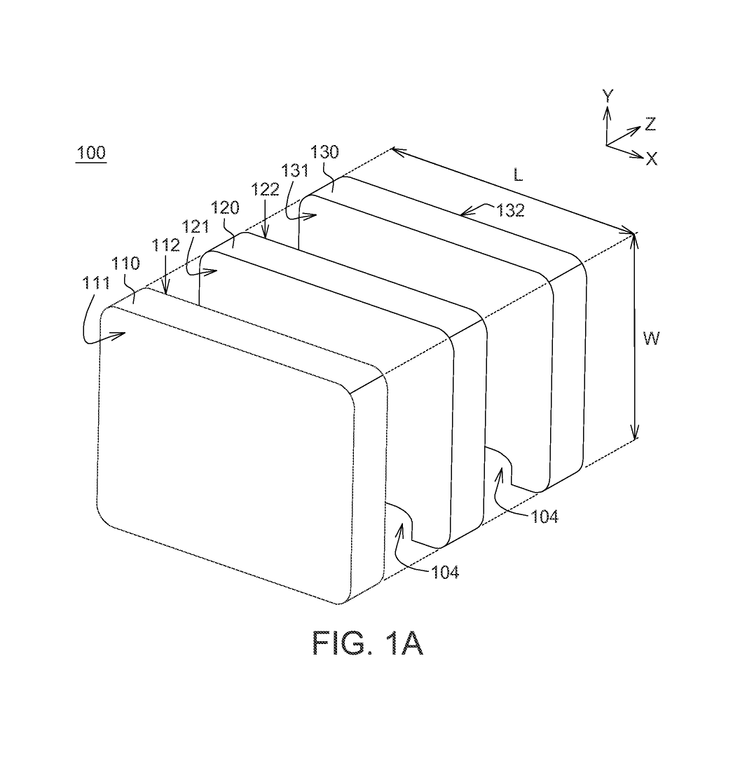

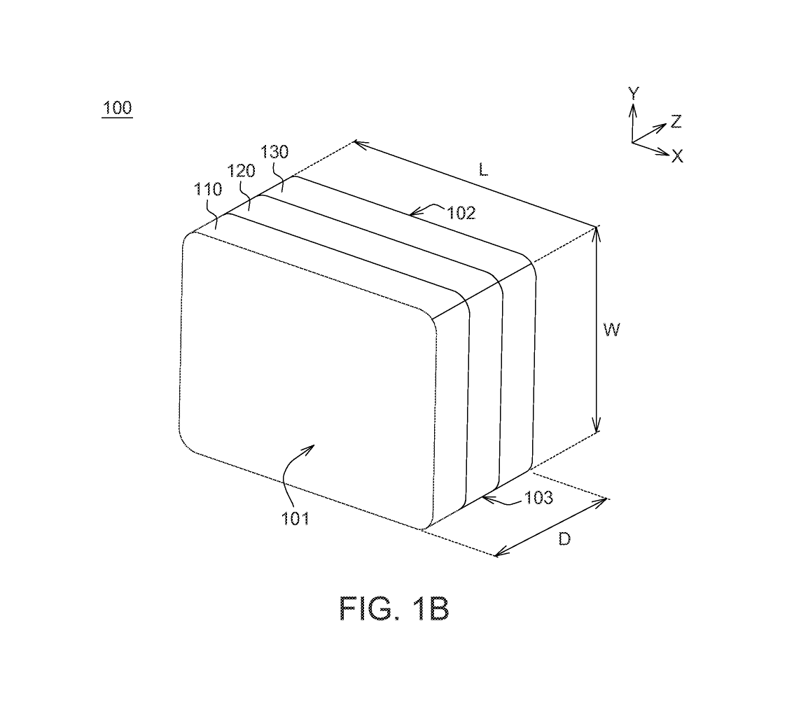

Referring to FIG. 1A and 1B, an explosion diagram and an assembly diagram of a communication device having multi-module assembly according to an embodiment of the invention are respectively shown. Based on the concept of modular design adopted in the present embodiment, several communication modules having different femto solution functions are disposed in different housings and are combined to form a body 100. As indicated in FIG. 1B, the body 100 after assembly has a front side 101, a rear side 102 and a plurality of lateral sides 103. The front side 101 and the rear side 102 both have a length dimension L and a width dimension W such as the dimensions in the X-axis direction and the Y-axis direction, respectively. The lateral sides 103 have a thickness dimension D in the Z-axis direction. For example, the body 100 after assembly is a cubic structure.

In FIG. 1A, the body 100 can be formed by a plurality of housings including a first housing 110, a second housing 120 and a third housing 130. The first housing 110 has a front side 111 and a rear side 112. The second housing 120 has a front side 121 and a rear side 122, and the front side 121 of the second housing 120 is opposite to the rear side 112 of the first housing 110. The third housing 130 has a front side 131 and a rear side 132, and the front side 131 of the third housing 130 is opposite to the rear side 122 of the second housing 120.

In an embodiment, the front side and the rear side of each housing have the same length dimension L and the same width dimension W, so that the appearance of the body 100 after assembly has dimension consistency.

The thickness dimension D of the body 100 after assembly is determined according to the quantity of housings, and the larger the quantity, the larger the thickness. The quantity of housings can be one or several according to actual needs. Since the increase or decrease in the quantity of housings only correspondingly increases or decreases the dimension in the Z-axis direction and does not affect the dimensions in other axial directions, the appearance of the body 100 after assembly is still a cubic structure.

In the body 100 after assembly, the rear side 112 of the first housing 110 ahead is connected with the front side 121 of the second housing 120 behind, and the rear side 122 of the second housing 120 is connected with the front side 131 of the third housing 130 behind as indicated in FIG. 1B. Since the seam between the housing ahead and the housing behind is very tiny and is unrecognizable to human eyes after the front and rear housings are connected to each other, the body 100 can thus satisfy the design requirement of seamlessness.

As indicated in FIG. 1A, a recess 104 is formed under the second housing 120 and the third housing 130 respectively. Referring to FIG. 1C, a left-rear view of a body 100 after assembly is shown. The rear of the body 100 has a recess 104, and two cables 105 can be extended to the recess 104. The two cables 105 can be a power line and a network line, and the plugs (not illustrated) of the two cables are inserted into two sockets (not illustrated) at the rear of the first housing 110. Necessary power is provided to the internal elements of the body 100 through the power line, and the body 100 can be connected to the Internet or a local area network (LAN) through the network line. Since the plugs of the two cables 105 are both embedded in the recess 104, the plugs will not be exposed and therefore the appearance design remains unaffected accordingly.

In an embodiment, the second housing 120 and the third housing 130 can be assembled on the first housing 110 independently or concurrently for the user to select necessary add-on communication modules. The first housing 110 has at least one communication module having femto solution function disposed therein. Even when the second housing 120 and the third housing 130 are not added to the body 100, the communication service provided by existing communication system is still available for use.

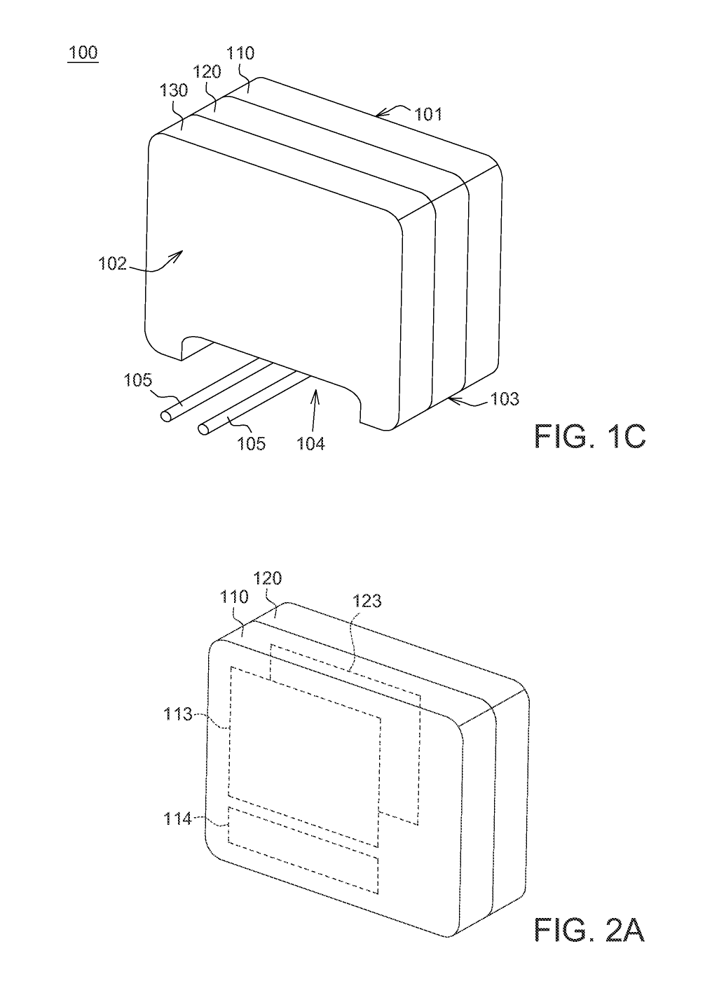

Two embodiments of adding or replacing communication module having femto solution function are disclosed below. As indicated in FIG. 2A, the first housing 110 has an existing communication module 113 and a base unit 114 disposed therein. The second housing 120 has a second communication module 123 disposed therein, wherein the second communication module 123 has second femto solution function. If the user would like to use the communication service provided by another communication system, the second housing 120 having the second communication module 123 can be added to the first housing 110 having the existing communication module 113. Referring to FIG. 2B. The third housing 130 has a third communication module 133 disposed therein, and the third communication module 133 has third femto solution function. If the use would like to add the third communication module 133 having third femto solution function to the existing communication module, the third housing 130 having third communication module 133 can be added to the second housing 120 directly as indicated in FIG. 1B, or the second housing 120 of FIG. 2A is dismounted first and then the third housing 130 having third communication module 133 is added to the first housing 110.

Both the second communication module 123 and the third communication module 133 can share the same base unit 114 and power with the existing communication module 113. The base unit 114 starts and initiates the existing communication module 113 and the newly added second communication module 123 and/or third communication module 133. Also, the base unit 114 can be connected to the Internet or the mobile service providers' network through a router or a modem (both are not illustrated) in the LAN. Firmware can be updated to change the settings of the base unit 114 so as to increase the compatibility between the body 100 and application software.

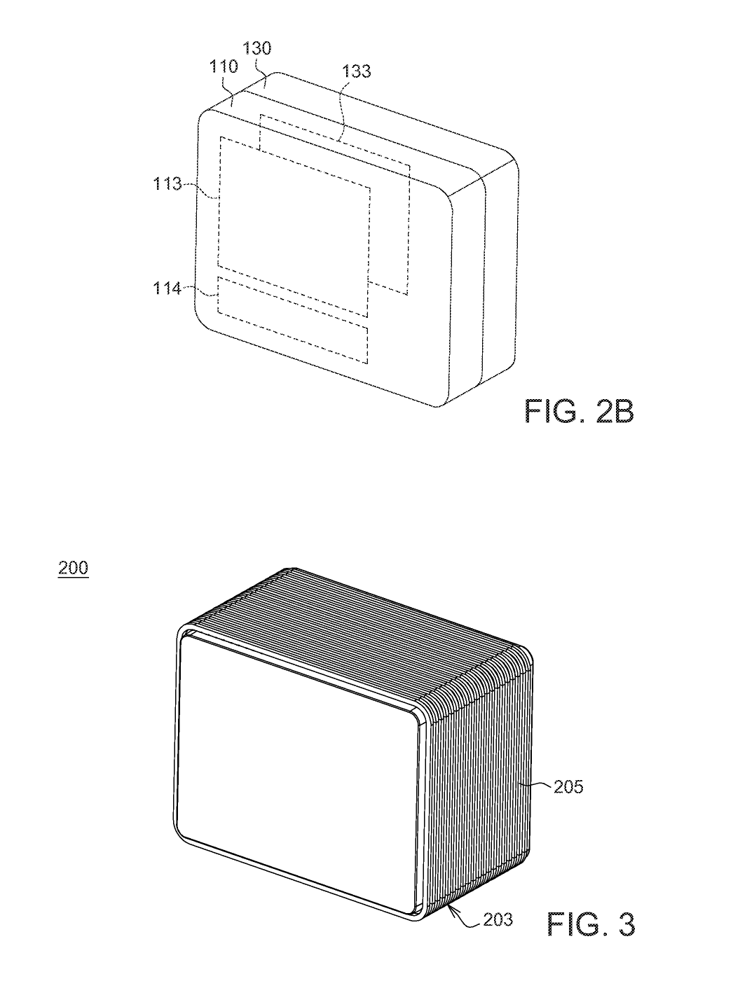

Referring to FIG. 3, a right-front view of a body 200 after assembly is shown. In an embodiment, a predetermined number of striped grooves 205 are formed on the lineament of the lateral sides 203 of the body 200 such that the seams on the body 100 after assembly are not recognizable to human eyes. The gaps and density of the grooves 205 can be adjusted according to actual needs. Since the shapes of the groove 205 and the seams look alike and it is very hard to tell the difference, the seams at the connection parts are thus unrecognizable to human eyes.

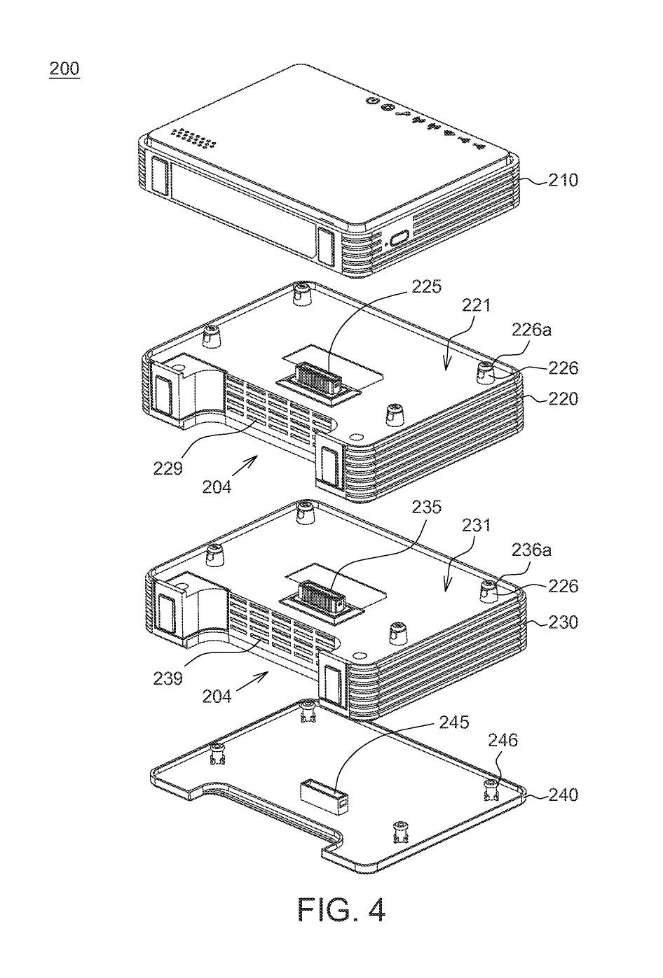

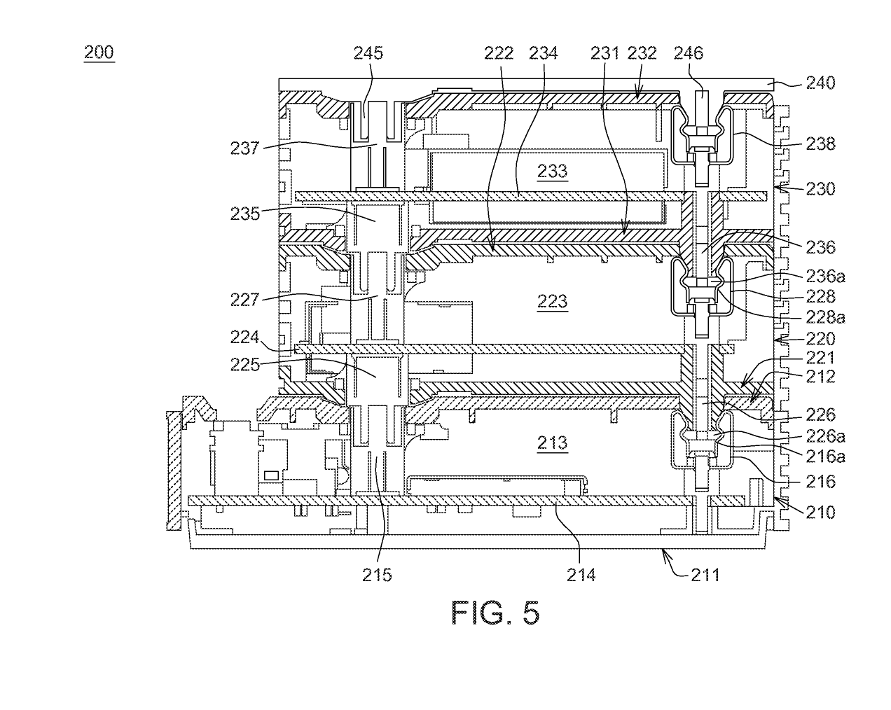

FIG. 4 shows an explosion diagram of a body 200 according to an embodiment of the invention. FIG. 5 shows a schematic diagram of internal structures of a body 200 after assembly. As indicated in FIGS. 4 and 5, the first communication module 213 has a first circuit board 214, a first connector 215 and a first ground spring 216. The first connector 215 and the first ground spring 216 are fixed above the first circuit board 214.

The second communication module 223 has a second circuit board 224, a second connector 225 and a first fixer 226. The second connector 225 and the first fixer 226 are fixed under the second circuit board 224.

The first connector 215 and the second connector 225 are mutually engaged and electrically connected to each other. The second connector 225 may be a male connecter, and the first connector 215 may be a female connecter. The second connector 225 is protruded from the front side 221 of the second housing 220 and inserted into the first connector 215 in a direction towards the rear side 212 of the first housing 210, such that the first circuit board 214 and the second circuit board 224 can transmit signals to each other.

That is, the first circuit board 214 and the second circuit board 224 are electrically connected to each other through a board-to-board connector. Besides, the first circuit board 214 and the second circuit board 224 can be grounded via the ground ends at the two connectors to avoid being interfered by electromagnetic waves.

The quantity of the first fixers 226 is four, for example. The first fixers 226 are disposed on the front side 221 of the second housing 220 and protruded from the front side 221 of the second housing 220 and inserted into the first ground spring 216 in a direction towards the rear side 212 of the first housing 210. The first ground spring 216 can be a U-shaped structure having a depressed opening portion 216a. Each first fixer 226 can be a T-shaped structure. The terminal portion 226a of the T-shaped structure is retained in the depressed opening portion 216a and cannot move, such that the first fixer 226 and the first ground spring 216 are engaged tightly and grounded. The first ground spring 216 not only increases the ground area but further has the function of thermal conductivity.

Similarly, the second communication module 223 and the third communication module 233 can be connected to each other in the same manner disclosed above. The second communication module 223 further has a third connector 227 and a second ground spring 228 fixed above the second circuit board 224. The third communication module 233 has a third circuit board 234, a fourth connector 235 and a second fixer 236. The fourth connector 235 and the second fixer 236 are fixed under the third circuit board 234.

The third connector 227 and the fourth connector 235 are mutually engaged and electrically connected to each other, such that the second circuit board 224 and the third circuit board 234 are electrically connected to each other through a board-to-board connector. The quantity of second fixers 236 is four, for example. The second fixer 236 is disposed on the front side 231 of the third housing 230 and is further protruded from the front side 231 of the third housing 230 and inserted into the second ground spring 228 in a direction towards the rear side 222 of the second housing 220. The second ground spring 228 can be a U-shaped structure having a depressed opening portion 228a. The second fixer 236 can be a T-shaped structure. The terminal portion 236a of the T-shaped structure is retained in the depressed opening portion 228a and cannot move, such that the second fixer 236 and the second ground spring 228 are engaged tightly and grounded.

Besides, the body 200 has a rear cover 240, for example. The rear cover 240 has a plurality of third fixers 246 which can be protruded and inserted into the third ground spring 238 in a direction towards the rear side 232 of the third housing 230, such that the third fixer 246 and the third ground spring 238 are engaged tightly and grounded. In addition, the rear cover 240 of the body 200 has an insulator 245 protruded and inserted into the fifth connector 237 in a direction towards the rear side 232 of the third housing 230 to avoid the unused fifth connector 237 being tarnished by dust.

As indicated in FIG. 4, the second housing 220 and the third housing 230 have a plurality of dissipation holes 229 and 239 hidden at the top of the recess 204, such that air convection may occur between external air and internal air to dissipate the waste heat. The dissipation holes 229 and 239 being hidden in the recess 204 do not destroy the appearance of the body 200. Moreover, the communication modules having femto solution function are designed as independent modules, such that the waste heat can be distributed and dissipated via the dissipation holes 229 and 239 and will not be gathered at single housing and interfere with each other.

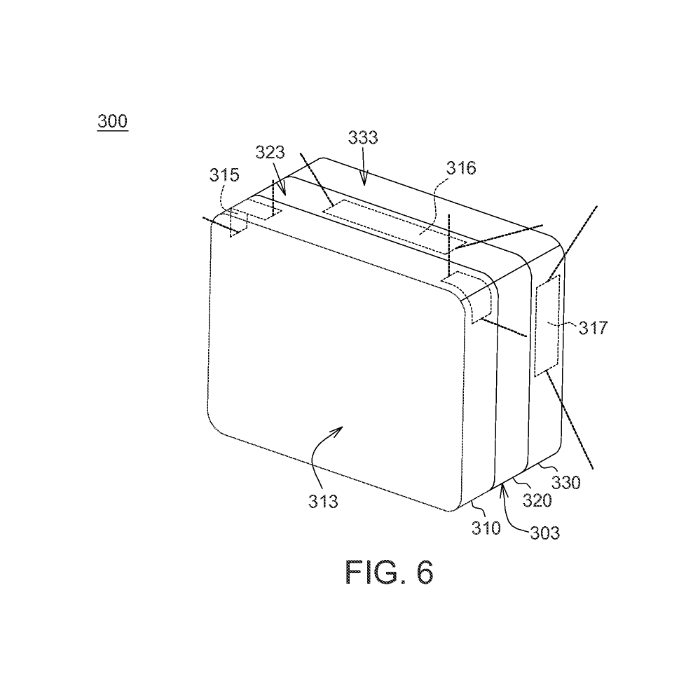

Referring to FIG. 6, a disposition diagram of antennas of communication device having multi-module assembly 300 a according to an embodiment of the invention is shown. In the present embodiment, the communication module having femto solution function transmits and receives signals with respective antennas. For example, the first communication module 313 has a first antenna 315 disposed on the lateral sides 303 of the body 300 and near a corner of the first housing 310. The second communication module 323 has a second antenna 316 disposed on the lateral sides 303 of the body 300 and near the top surface of the second housing 320. The third communication module 333 has a third antenna 317 disposed on the lateral sides 303 of the body 300 and near a side surface of the third housing 330. The lateral sides 303 of the body 300 have sufficient area for the disposition of the antennas, and the antennas are directed towards different directions. Therefore, the body 300 can use two or more than two communication modules having femto solution functions without incurring interference between the antennas.

The communication module having femto solution function disclosed above is a communication module conformed to the universal mobile telecommunication system (UMTS, 3G communication system) standard or the long term evolution (LTE, 4G communication system) standard, or supporting the IEEE802.11a/b/g wireless network communication protocol, the Bluetooth communication or the worldwide interoperability for microwave access (WIMAX) standard.

Besides, the first antenna 315 may be a wireless network antenna applicable to WiFi waveband. The second antenna 316 may be a 3G mobile communication antenna applicable to various wavebands such as GSM/GPRS/UMTS/HSDPA/WCDMA wavebands. The third antenna 317 may be a 4G mobile communication antenna applicable to 4G LTE wavebands. The invention does not have specific restrictions regarding the antennas.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A communication device having multi-module assembly, wherein the communication device comprises:
a body having front side, a rear side and a plurality of lateral sides, wherein the front side and the rear side both have a length dimension and a width dimension, the lateral sides have a thickness dimension, the body is a combination of a plurality of housings with the same length dimension and the same width dimension, and the rear side of a housing ahead is connected with the front side of another housing behind;
a first communication module disposed in a first housing of the body; and
a second communication module disposed in a second housing of the body.

2. The communication device according to claim 1, wherein the first communication module has a first connector, the second communication module has a second connector, and the first connector and the second connector are mutually engaged and electrically connected to each other.

3. The communication device according to claim 1, wherein the first communication module has at least one first ground spring, the second communication module has at least one first fixer, the first fixer is inserted into the first ground spring from the front side of the second housing towards the rear side of the first housing.

4. The communication device according to claim 1, wherein the first communication module has a first circuit board, the second communication module has a second circuit board, the first circuit board is disposed in the first housing, the second circuit board is disposed in the second housing, and the first circuit board is electrically connected to the second circuit board through a board-to-board connector.

5. The communication device according to claim 1, wherein the first communication module has a first antenna, the second communication module has a second antenna, the first antenna and the second antenna are located on the lateral sides of the body and directed towards different directions.

6. The communication device according to claim 1, further comprising a third communication module disposed in a third housing of the body.

7. The communication device according to claim 6, wherein the first communication module has a first connector, the second communication module has a second connector and a third connector, the third communication module has a fourth connector, the first connector and the second connector are mutually engaged and electrically connected to each other, and the third connector and the fourth connector are mutually engaged and electrically connected to each other.

8. The communication device according to claim 6, wherein the first communication module has at least one first ground spring, the second communication module has at least one first fixer and at least one second ground spring, the third communication module has at least one second fixer, the first fixer is inserted into the first ground spring from the front side of the second housing towards the rear side of the first housing, the second fixer is inserted into the second ground spring from the front side of the third housing towards the rear side of the second housing.

9. The communication device according to claim 6, wherein the first communication module has a first circuit board, the second communication module has a second circuit board, the third communication module has a third circuit board, the first circuit board is disposed in the first housing, the second circuit board is disposed in the second housing, the third circuit board is disposed in the third housing, the first circuit board is electrically connected to the second circuit board through a board-to-board connector, and the second circuit board is electrically connected to the third circuit board through a board-to-board connector.

10. The communication device according to claim 6, wherein the first communication module has a first antenna, the second communication module has a second antenna, the third communication module has a third antenna, and the first antenna, the second antenna and the third antenna are respectively located on the lateral sides of the body and directed towards different directions.
